(19) United States
(12) Patent Application Publication
(10) Pub. No.: US 2024/0188397 A1
(43) Pub. Date: Jun. 6, 2024

(54) COATING COMPOSITION AND DISPLAY DEVICE COMPRISING THE SAME

(71) Applicant: Samsung Display Co., LTD., Yongin-si (KR)

(72) Inventors: Heung Shik PARK, Yongin-si (KR); El Ly GIL, Yongin-si (KR); Mi Ran JI, Yongin-si (KR); Beohm Rock CHOI, Yongin-si (KR)

(73) Assignee: Samsung Display Co., LTD., Yongin-si (KR)

(21) Appl. No.: 18/350,125

(22) Filed: Jul. 11, 2023

(30) Foreign Application Priority Data
Nov. 23, 2022 (KR) 10-2022-0157876

(51) Int. Cl. H10K 59/80; C09D 4/06; C09D 7/45; C09D 7/65; C09D 133/06

(52) U.S. Cl. CPC H10K 59/879; C09D 4/06; C09D 7/45; C09D 7/65; C09D 133/062; H10K 59/873; H10K 59/12

(57) ABSTRACT

Embodiments provide coating composition and a display device. The coating composition comprises a first monomer represented by Chemical Formula 1 or Chemical Formula 2, a second monomer comprising an acrylate monomer, a photoinitiator, a surfactant, and a solvent, wherein Chemical Formula 1 and Chemical Formula 2 are explained in the specification:

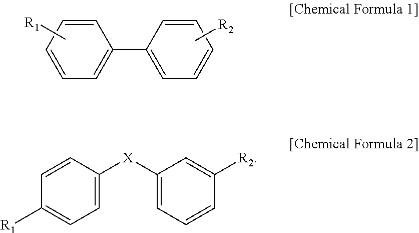

### CROSS REFERENCE TO RELATED APPLICATION(S)

This application claims priority to and benefits of Korean Patent Application No. 10-2022-0157876 under 35 U.S.C. § 119, filed on Nov. 23, 2022 in the Korean Intellectual Property Office, the entire contents of which are incorporated herein by reference.

### BACKGROUND

### 1. Technical Field

The disclosure relates to a coating composition and a display device including the same.

### 2. Description of the Related Art

As an information-oriented society evolves, various demands for display devices continue to increase. For example, display devices are being employed by a variety of electronic devices such as smart phones, digital cameras, laptop computers, navigation devices, and smart televisions.

Display devices may be flat panel display devices such as a liquid-crystal display device, a field emission display device, and a light-emitting display device. Examples of light-emitting display devices include an organic light-emitting display device including organic light-emitting elements, an inorganic light-emitting display device including inorganic light-emitting elements such as inorganic semiconductor, and a micro light-emitting display device including micro light-emitting elements.

Among display devices, an organic light-emitting display device includes a self-luminous element, e.g., an organic light-emitting element. An organic light-emitting element may include two opposing electrodes and an emissive layer interposed therebetween. In an organic light-emitting element, electrons and holes supplied from the two electrodes are recombined in the emissive layer to generate excitons, and the generated transition from an excited state to a ground state, and accordingly, light can be emitted.

Such an organic light-emitting element requires no separate light source such as a backlight unit, and thus it consumes less power and can be made light and thin, as well as exhibiting high-quality characteristics such as wide viewing angle, high luminance, high contrast, and fast response speed. Accordingly, organic light-emitting display devices are attracting attention as a next generation display device.

### SUMMARY

Embodiments provide a coating composition capable of avoiding a decrease in the output efficiency and a display device including the coating composition.

The disclosure is not limited to the embodiments listed above, and further embodiments of the disclosure will be apparent to those skilled in the art from the following descriptions.

Embodiments provide a coating composition which may include a first monomer represented by Chemical Formula 1 or Chemical Formula 2, a second monomer including an acrylate monomer, a photoinitiator, a surfactant, and a solvent:

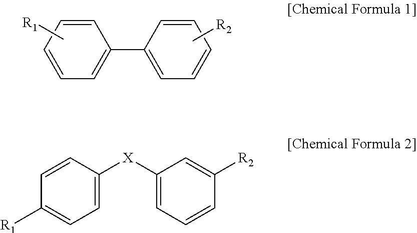

wherein in Chemical Formula 1 and Chemical Formula 2,
R₁ and R₂ may each independently be hydrogen,

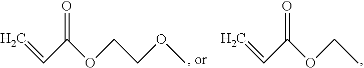

and
X may be O or S.

In an embodiment, the first monomer represented by Chemical Formula 1 or Chemical Formula 2 may be represented by one of the following formulas:

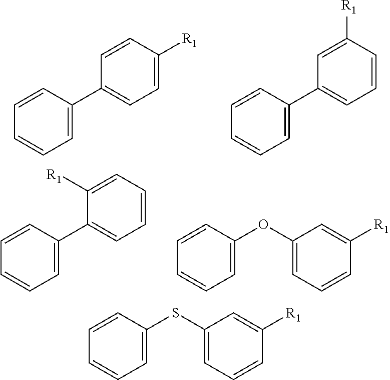

wherein in the formulas above,
R₁ may be

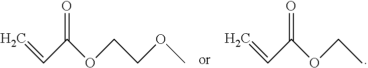

In an embodiment, the first monomer represented by Chemical Formula 1 may include the following compound:

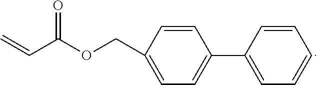 [SMILES: C=CC(=O)OCc1ccc(-c2ccccc2)cc1]

In an embodiment, the first monomer represented by Chemical Formula 1 or Chemical Formula 2 may be represented by one of the following formulas:

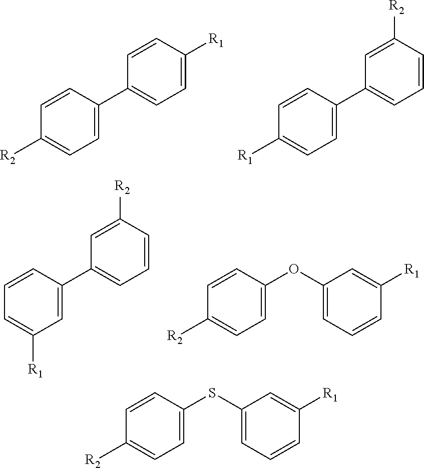

wherein in the formulas above,
R₁ and R₂ may each independently be hydrogen,

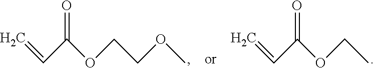

In an embodiment, the second monomer may include a polyethylene glycol diacrylate or a diol diacrylate.

In an embodiment, a solid content of the composition per 100 wt %, excluding the solvent, may include: about 50 wt % to about 90 wt % of the first monomer, about 5 wt % to about 40 wt % of the second monomer, about 0.1 wt % to about 10 wt % of the photoinitiator, and about 0.1 wt % to about 10 wt % of the surfactant.

In an embodiment, a content of the solvent may be in a range of about 50 wt % to about 90 wt %, per 100 wt % of the total coating composition.

In an embodiment, a viscosity of the coating composition may be in a range of about 10 cps to about 25 cps.

In an embodiment, a surface tension of the coating composition may be in a range of about 22 mN/m to about 30 mN/m.

Embodiments provide a display device which may include: a light-emitting element disposed on a substrate, the light-emitting element including a first electrode, an organic emitting layer, a second electrode, and an emission area;
a first planarization layer disposed on the light-emitting element and including an opening portion overlapping the emission area; and a second planarization layer disposed on the first planarization layer and covering the opening portion,
wherein the second planarization layer includes a first monomer represented by Chemical Formula 1 or Chemical Formula 2, a second monomer including an acrylate monomer, a photoinitiator, and a surfactant:

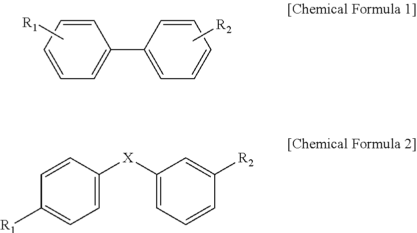

wherein in Chemical Formula 1 and Chemical Formula 2,
R₁ and R₂ may each independently be hydrogen,

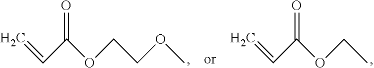

and
X may be O or S.

In an embodiment, the first monomer represented by Chemical Formula 1 or Chemical Formula 2 may be represented by one of the following formulas:

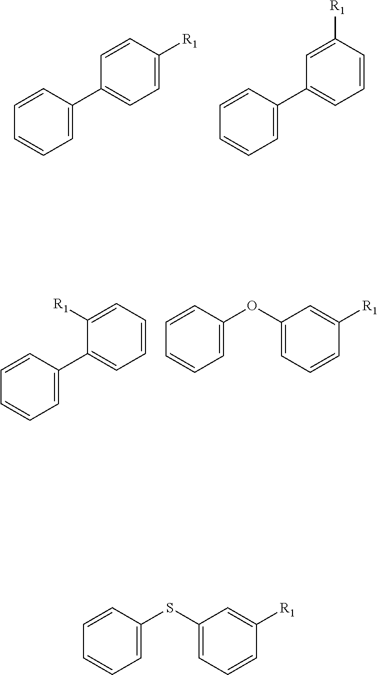

wherein in the formulas above,
R₁ may be

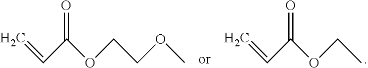

In an embodiment, the first monomer represented by Chemical Formula 1 may include the following compound:

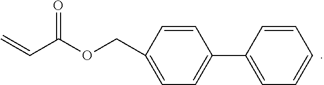 [SMILES: C=CC(=O)OCc1ccc(-c2ccccc2)cc1]

In an embodiment, the first monomer represented by Chemical Formula or Chemical Formula 2 may be represented by one of the following formulas:

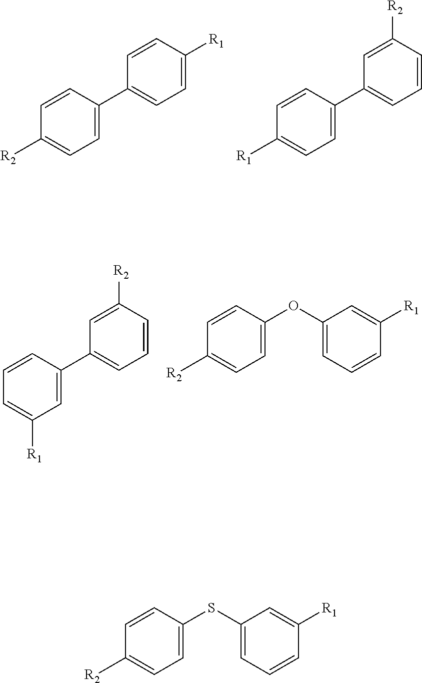

wherein in the formulas above,
R₁ and R₂ may each independently be hydrogen,

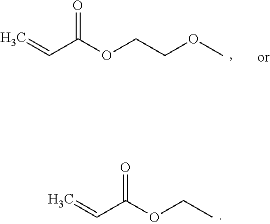

In an embodiment, the second monomer may include a polyethylene glycol diacrylate or a diol diacrylate.

In an embodiment, a refractive index of the second planarization layer may be in a range of about 1.58 to about 1.65.

In an embodiment, the refractive index of the second planarization layer may be greater than a refractive index of the first planarization layer by 0.05 or more.

In an embodiment, a modulus of the second planarization layer may be in a range of about 0.1 GPa to about 1.5 GPa.

In an embodiment, an elongation of the second planarization layer may be equal to or greater than about 5%.

In an embodiment, side surfaces of the first planarization layer may form an inner circumferential surface of the opening portion having a regular taper angle.

In an embodiment, the display device may further include a thin-film encapsulation layer disposed between the light-emitting element and the first planarization layer, and a touch sensor layer disposed between the thin-film encapsulation layer and the first planarization layer.

According to an embodiment of the disclosure, a second planarization layer including a first monomer having a high refractive index and a second monomer having a low viscosity is formed in a display device, so that the second planarization layer can have a high refractive index and can be coated well without inorganic particles. Accordingly, it is possible to address issues of light scattering, light reflection, and a difference in refractive index between the surface and the inner region of the second planarization layer. Thus the light efficiency of the display device can be improved.

It is to be understood that the embodiments above are described in a generic and explanatory sense only and not for the purpose of limitation, and the disclosure is not limited to the embodiments described above.

### BRIEF DESCRIPTION OF THE DRAWINGS

The above and other aspects and features of the disclosure will become more apparent by describing in detail embodiments thereof with reference to the accompanying drawings, in which:

FIG. 1 is a schematic plan view of a display device according to an embodiment.

FIG. 2 is a schematic cross-sectional view taken along line I-I′ of FIG. 1.

FIG. 3 is a schematic plan view showing an example of the display unit of FIG. 2 in detail.

FIG. 4 is a schematic plan view showing an example of the touch detecting unit of FIG. 2.

FIG. 5 is an enlarged schematic plan view of area A of FIG. 4.

FIG. 6 is a schematic cross-sectional view taken along line II-II′ of FIG. 5.

FIG. 7 is an enlarged schematic plan view of the first planarization layer and the sub-pixels in area A of FIG. 4.

FIG. 8 is a graph showing the refractive index of the coating film versus the content of the first monomer in the coating composition.

FIG. 9 is a graph showing measurement results of the light efficiencies of the display devices according to the Comparative Example Sample #1, and Sample #2.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like reference numbers and reference characters refer to like elements throughout.

In the specification, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the specification, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group consisting of” for the purpose of its meaning and interpretation. For example, “at least one of A, B, and C” may be understood to mean A only, B only, C only, or any combination of two or more of A, B, and C, such as ABC, ACC, BC, or CC. When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The features of the various embodiments of the disclosure may be combined or combined with each other, in part or in whole, and technically various interlocking and driving are possible. Each embodiment may be implemented independently of each other or may be implemented together in an association.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, embodiments of the disclosure will be described with reference to the accompanying drawings.

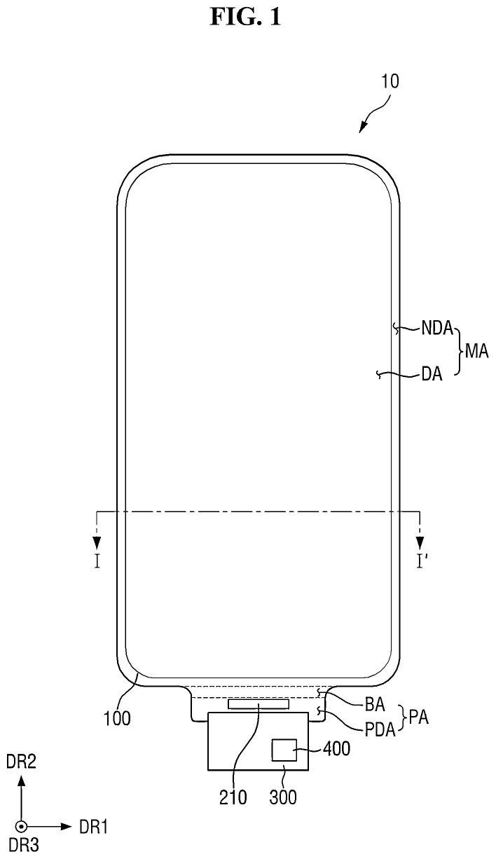

FIG. 1 is a schematic plan view of a display device according to an embodiment.

As used herein, the terms “above,” “top” and “upper surface” refer to the upper side of a display device 10, i.e., the side indicated by the arrow in the third direction DR3, whereas the terms “below,” “bottom” and “lower surface” refer to the opposite side in the third direction DR3. As used herein, the terms “left,” “right,” “upper” and “lower” sides indicate relative positions when the display device 10 is viewed from the top (for example, in a plan view). For example, the “right side” refers to the side indicated by the arrow of the first direction DR1, the “left side” refers to the opposite side to the side indicated by the arrow of the first direction DR1, the “upper side” refers to the side indicated by the arrow of the second direction DR2, and the “lower side” refers to the opposite side to the side indicated by the arrow the second direction DR2.

Referring to FIG. 1, a display device 10 is for displaying moving images or still images. The display device 1 may be used as the display screen of portable electronic devices such as a mobile phone, a smart phone, a tablet PC, a smart watch, a watch phone, a mobile communications terminal, an electronic notebook, an electronic book, a portable multimedia player (PMP), a navigation device, and an ultra mobile PC (UMPC), as well as the display screen of various products such as a television, a notebook, a monitor, a billboard, and an Internet of Things (IOT). The display device 10 may be one of an organic light-emitting display device, a liquid-crystal display device, a plasma display device, a field emission display device, an electrophoretic display device, an electrowetting display device, a quantum dot light- emitting display device, a micro LED display device, and the like. In the following description, an organic light-emitting display device is described as an example of the display device 10. It is, however, to be understood that embodiments are not limited thereto.

According to an embodiment, the display device 10 may include a display panel 100, a display driving circuit 210, a circuit board 300 and a touch driving circuit 400.

The display panel 100 may include a main area MA and a protruding area PA protruding from a side of the main area MA.

The main area MA may be formed in a rectangular plane having shorter sides in a first direction DR1 and longer sides in a second direction DR2 that intersects the first direction DR1. Each of the corners where the short side in the first direction DR1 meets the longer side in the second direction DR2 may be rounded at a selected curvature or may be at a right angle. The shape of the display device 10 in a plan view is not limited to a quadrangular shape, but may be formed as another polygonal shape, as a circular shape, or as an elliptical shape. The main area MA may be formed to be flat, but embodiments are not limited thereto. The main area MA may include curved portions formed at left and right ends thereof. The curved portions may have a constant curvature or varying curvatures.

The main area MA may include a display area DA where pixels are formed to display images, and a non-display area NDA adjacent to the display area DA (for example, around the display area DA).

Scan lines, data lines, and power lines connected to the pixels may be disposed in the display area DA, in addition to the pixels. When the main area MA includes a curved portion, the display area DA may be disposed on the curved portion. For example, images of the display panel 100 may also be seen on the curved portion.

The non-display area NDA may be defined as an area from an outer side of the display area DA to an outer edge of the display panel 100. In the non-display area NDA, a scan driver that applies scan signals to scan lines, and link lines that connect the data lines with the display driving circuit 210 may be disposed.

The protruding area PA may protrude from a side of the main area MA. For example, the protruding area PA may protrude from a lower side of the main area MA as shown in FIG. 1. A length of the protruding area PA in the first direction DR1 may be smaller than a length of the main area MA in the first direction DR1.

The protruding area PA may include a bending area BA and a pad area PDA. For example, the pad area PDA may be disposed on a side of the bending area BA, and the main area MA may be disposed on an opposite side of the bending area BA. For example, the pad area PDA may be disposed on a lower side of the bending area BA, and the main area MA may be disposed on an upper side of the bending area BA.

The display panel 100 may be formed to be flexible so that it can be curved, bent, folded, or rolled. Therefore, the display panel 100 may be bent at the bending area BA in the third direction DR3, which is a thickness direction. For example, the surface of the pad area PDA of the display panel 100 may face upward before the display panel 100 is bent, while the surface of the pad area PDA of the display panel 100 may face downward after the display panel 100 is bent. As a result, since the pad area PDA is disposed under the main area MA, the pad area PDA may overlap the main area MA.

Pads that are electrically connected to the display driving circuit 210 and to the circuit board 300 may be disposed in the pad area PDA of the display panel 100.

The display driving circuit 210 outputs signals and voltages for driving the display panel 100. For example, the display driving circuit 210 may apply data voltages to the data lines. For example, the display driving circuit 210 may apply supply voltage to the power line and may apply scan control signals to the scan driver. The display driving circuit 210 may be implemented as an integrated circuit (IC) and may be attached to the display panel 100 in a pad area PDA by a chip on glass (COG) technique, by a chip on plastic (COP) technique, or by ultrasonic bonding. For example, the display driving circuit 210 may be mounted on the circuit board 300.

The pads may include display pads that are electrically connected to the display driving circuit 210 and touch pads electrically that are connected to touch lines.

The circuit board 300 may be attached to the pads using an anisotropic conductive film. In this manner, the lead lines of the circuit board 300 may be electrically connected to the pads. The circuit board 300 may be a flexible printed circuit board, a printed circuit board, or a flexible film such as a chip-on-film.

The touch driving circuit 400 may be connected to touch electrodes of a touch sensor layer TSL of the display panel 100. The touch driving circuit 400 applies driving signals to the touch electrodes of the touch sensor layer TSL and measures capacitances of the touch electrodes. The driving signals may have driving pulses. The touch driving circuit 400 may not only determine whether a touch is input based on the capacitances, but may also calculate touch coordinates of the position where the touch is input.

The touch driving circuit 400 may be disposed on the circuit board 300. The touch driving circuit 400 may be implemented as an integrated circuit (IC) and may be mounted on the circuit board 300.

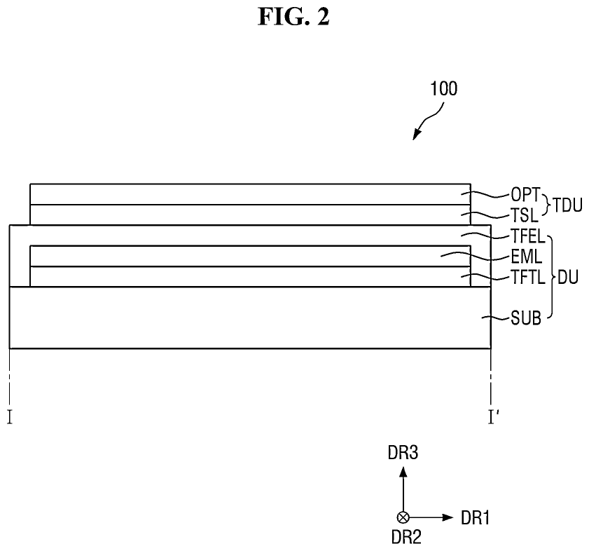

FIG. 2 is a schematic cross-sectional view taken along line I-I′ of FIG. 1.

Referring to FIG. 2, the display device 100 may include: a display unit DU having a substrate SUB, a thin-film transistor layer TFTL disposed on the substrate SUB, an emission material layer EML, and a thin-film encapsulation layer TFEL; and a touch detecting unit TDU having the touch sensor layer TSL and an optical layer OPT.

The substrate SUB may be formed of an insulating material such as glass, quartz, or a polymer material. Examples of a polymer material may include polyethersulphone (PES), polyacrylate (PA), polyacrylate (PAR), polyetherimide (PEI), polyethylene naphthalate (PEN), polyethylene terephthalate (PET), polyphenylene sulfide (PPS), polyallylate, polyimide (PI), polycarbonate (PC), cellulose triacetate (CAT), cellulose acetate propionate (CAP), or a combination thereof. In another embodiment, the substrate SUB may include a metallic material.

The substrate SUB may be a rigid substrate or a flexible substrate that can be bent, folded, rolled, and so on. When the substrate SUB is a flexible substrate, it may be formed of polyimide (PI), but embodiments are not limited thereto.

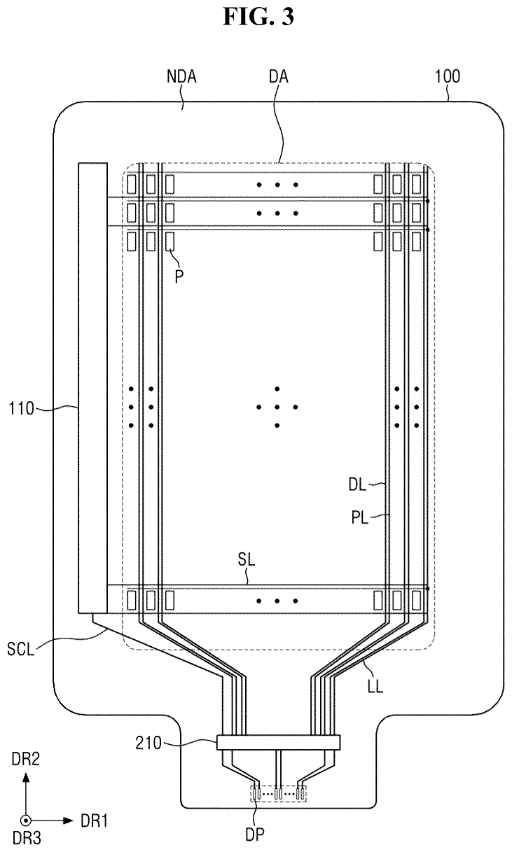

The thin-film transistor layer TFTL may be disposed on the substrate SUB. On the thin-film transistor layer TFTL, scan lines, data lines, power supply lines, scan control lines, routing lines connecting the pads with the data lines may be formed, as well as thin-film transistors in the pixels. The thin-film transistors may each include a gate electrode, a semiconductor layer, a source electrode, and a drain electrode. When a scan driver 110 is formed in the non-display area NDA of the display panel 100 as shown in FIG. 3, the scan driver 110 may include thin-film transistors.

The thin-film transistor layer TFTL may be disposed in the display area DA and in the non-display area NDA. For example, the thin-film transistors in the pixels, the scan lines, the data lines, and the power supply lines on the thin-film film transistor layer TFTL may be disposed in the display area DA. The scan control lines and the link lines on the thin-film transistor layer TFTL may be disposed in the non-display area NDA.

The emission material layer EML may be disposed on the thin-film transistor layer TFTL. The emission material layer EML may include: pixels including a first electrode, an emissive layer, and a second electrode; and a pixel-defining layer. The emissive layer may be an organic emissive layer containing an organic material. For example, the emissive layer may include a hole transporting layer, an organic light-emitting layer, and an electron transporting layer. When a voltage is applied to the first electrode and a cathode voltage is applied to the second electrode through the thin-film transistor on the thin-film transistor layer TFTL, the holes and electrons move to the organic light-emitting layer through the hole transporting layer and the electron transporting layer, respectively, such that they combine in the organic light-emitting layer to emit light. The pixels on the emission material layer EML may be disposed in the display area DA.

The thin-film encapsulation layer TFEL may be disposed on the emission material layer EML. The thin-film encapsulation layer TFEL may prevent oxygen and/or moisture from permeating into the emission material layer EML. In an embodiment, a thin-film encapsulation layer TFEL may include at least one inorganic layer. The inorganic film may include silicon oxide (SiNₓ), silicon oxynitride (SiNₓO_{y}), silicon oxide (SiOₓ), titanium oxide (TiO₂), or aluminum oxide (Al₂O₃), but embodiments are not limited thereto. The thin-film encapsulation layer TFEL may protect the emission material layer EML from foreign substances such as dust. In an embodiment, the thin-film encapsulation layer TFEL may include at least one organic layer. The organic layer may be formed of an acryl resin, an epoxy resin, a phenolic resin, a polyamide resin, or a polyimide resin, but embodiments are not limited thereto.

The thin-film encapsulation layer TFEL may be disposed in the display area DA as well as the non-display area NDA. For example, the thin-film encapsulation layer TFEL may cover the display area DA and the emission material layer EML and may cover the thin-film transistor layer TFTL in the non-display area NDA.

The touch sensor layer TSL may be disposed (for example, directly disposed) on the thin-film encapsulation layer TFEL. When the touch sensor layer TSL is directly disposed on the thin-film encapsulation layer TFEL, a thickness of the display device 10 can be reduced, as compared with a display device in which a separate touch panel including the touch sensor layer TSL is attached on the thin-film encapsulation layer TFEL.

The touch sensor layer TSL may include touch electrodes for sensing a user's touch by capacitive sensing, and touch lines for connecting the pads with the touch electrodes. For example, the touch sensor layer TSL can sense a user's touch by self-capacitance sensing or by mutual capacitance sensing.

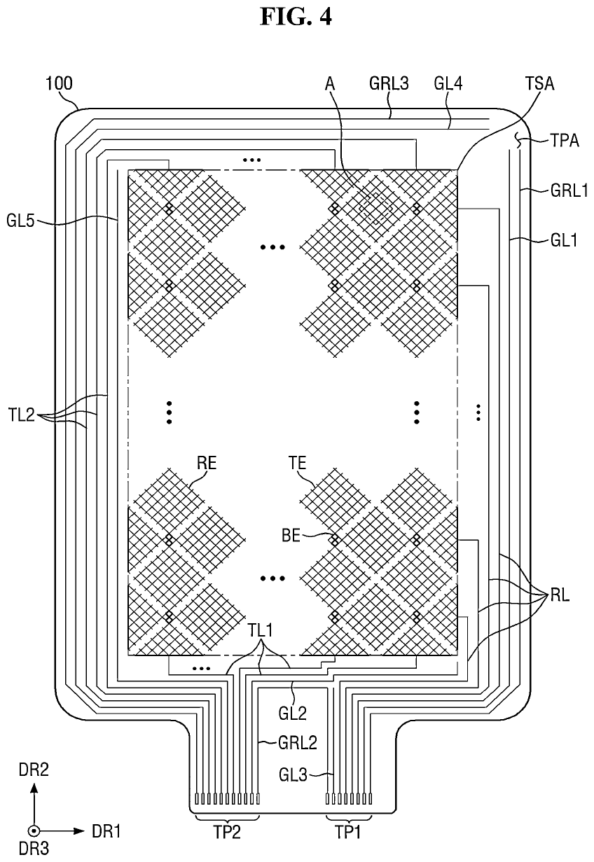

The touch electrodes of the touch sensor layer TSL may be disposed in a touch sensor area TSA overlapping the display area DA as shown in FIG. 4. The touch lines of the touch sensor layer TSL may be disposed in a touch peripheral area TPA overlapping the non-display area NDA as shown in FIG. 4.

The optical layer OPT may be disposed on the touch sensor layer TSL. The optical layer OPT totally reflects light that is emitted from the emission material layer EML and that would travel toward a side surface rather than in the third direction DR3 of the display panel 100, such that the light travels in the third direction DR3 of the display panel 100. Although the optical layer OPT is formed on the touch sensor layer TSL as a separate layer in FIG. 4, the disclosure is not limited thereto. For example, the touch sensor layer TSL and the optical layer OPT may be formed as a single layer.

A polarizing plate and a cover window may be further disposed on the optical layer OPT. For example, the optical layer OPT and the polarizing plate may be attached together by a transparent adhesive member such as an optically clear adhesive (OCA) film.

FIG. 3 is a schematic plan view showing an example of the display unit of FIG. 2 in detail.

For convenience of illustration, FIG. 3 shows only pixels P, scan lines SL, data lines DL, a power line PL, scan control lines SCL, a scan driver 110, a display driving circuit 210 and display pads DP of the display unit DU.

Referring to FIG. 3, the scan lines SL, the data lines DL, the power line PL and the pixels P may be disposed in the display area DA. The scan lines SL may be arranged in the first direction DR1, while the data lines DL may be arranged in the second direction DR2 intersecting the first direction DR1. The power line PL may include at least one line in parallel with the data lines DL in the second direction DR2, and lines branching off from the at least one line in the first direction DR1.

Each of the pixels P may be connected to at least one of the scan lines SL, one of the data lines DL, and the power line PL. Each of the pixels P may include thin-film transistors including a driving transistor and at least one switching transistor, an organic light-emitting diode, and a capacitor. When a scan signal is applied from the scan line SL, each of the pixels P receives a data voltage of the data line DL and supplies a driving current to the organic light-emitting diode according to the data voltage applied to the gate electrode, so that light is emitted.

The scan driver 110 is connected to the display driving circuit 210 through at least one scan control line SCL. Accordingly, the scan driver 110 may receive the scan control signal of the display driver circuit 210. The scan driver 110 generates scan signals according to a scan control signal and supplies the scan signals to the scan lines SL.

Although the scan driver 110 is formed in the non-display area NDA on the left side of the display area DA in FIG. 3, the disclosure is not limited thereto. For example, the scan driver 110 may be formed in the non-display area NDA on a left outer side, as well as in the non-display area NDA on a right outer side of the display area DA.

The display driving circuit 210 is connected to the display pads DP and receives digital video data and timing signals. The display driving circuit 210 converts the digital video data into analog positive/negative data voltages and supplies them to the data lines DL through the link lines LL. The display driving circuit 210 generates and supplies a scan control signal for controlling the scan driver 110 through the scan control line SCL. The pixels P, to which the data voltages are to be supplied, are selected by the scan signals of the scan driver 110, and the data voltages are supplied to the selected pixels P. The display driver circuit 210 may be implemented as an integrated circuit (IC) and may be attached to the substrate SUB by a chip on glass (COG) technique, by a chip on plastic (COP) technique, or by ultrasonic bonding.

FIG. 4 is a schematic plan view showing an example of the touch detecting unit of FIG. 2.

For convenience of illustration, FIG. 4 shows only the touch electrodes TE and RE, the touch lines, and the touch pads TP.

Referring to FIG. 4, the touch detecting unit TDU includes a touch sensor area TSA for detecting a user's touch, and a touch peripheral area TPA disposed around the touch sensor area TSA. The touch sensor area TSA may overlap the display area DA of the display panel 100, and the touch peripheral area TPA may overlap the non-display area NDA of the display unit DU.

The touch electrodes TE and RE may be disposed in the touch sensor area TSA. The touch electrodes TE and RE may include sensing electrodes RE that are electrically connected with one another in the first direction DR1, and driving electrodes TE that are electrically connected with one another in the second direction DR2 intersecting the first direction DR1. Although the sensing electrodes RE and the driving electrodes TE are formed in a diamond-like shape in a plan view in FIG. 4, the disclosure is not limited thereto.

In order to prevent a short-circuit from being created between the sensing electrodes RE and the driving electrodes TE as they cross each other, the driving electrodes TE adjacent to each other in the second direction DR2 may be electrically connected to each other via connection electrodes BE. For example, the driving electrodes TE and the sensing electrodes RE may be disposed on one layer, while the connection electrodes BE may be disposed on a different layer from the driving electrodes TE and the sensing electrodes RE. The sensing electrodes RE that are electrically connected with one another in the first direction DR1, and the driving electrodes TE that are electrically connected with one another in the second direction DR2 may be electrically insulated from one another.

The touch lines may be disposed in the touch peripheral area TPA. The touch lines may include sensing lines RL connected to the sensing electrodes RE, and first driving lines TL1 and second driving lines TL2 connected to the driving electrodes TE.

The sensing electrodes RE that are disposed on the right side of the touch sensor area TSA may be connected to the sensing lines RL. For example, a portion of the sensing electrodes RE electrically connected in the first direction DR1 that are disposed at the right end may be connected to the sensing lines RL. The sensing lines RL may be connected to first touch pads TP1. Thus, the touch driving circuit 400 may be electrically connected to the sensing electrodes RE.

The driving electrodes TE disposed on the lower side of the touch sensor area TSA may be connected to the first driving lines TL1, while the driving electrodes TE disposed on the upper side of the touch sensor area TSA may be connected to the second driving lines TL2. For example, a portion of the driving electrodes TE electrically connected to one another in the second direction DR2 on the lower end may be connected to the first driving lines TL1, while another portion of the driving electrodes TE disposed on the upper end may be connected to the second driving lines TL2. The second driving lines TL2 may be connected to the driving electrodes TE on the upper side of the touch sensor area TSA via the left outer side of the touch sensor area TSA. The first driving lines TL1 and the second driving lines TL2 may be connected to the second touch pads TP2. Thus, the touch driving circuit 400 may be electrically connected to the driving electrodes TE.

The touch electrodes TE and RE may be driven in a self-capacitance sensing scheme or in a mutual-capacitance sensing scheme. When the touch electrodes TE and RE are driven in a mutual-capacitance sensing scheme, the driving signals may be supplied to the driving electrodes TE through the first driving lines TL1 and the second driving lines TL2, such that the mutual capacitances formed at the intersections between the sensing electrodes RE and the driving electrodes TE are charged. Changes in the amount of the charges of the sensing electrodes RE are measured through the sensing lines RL, and it is determined whether a touch input is made according to the changes in the amount of the charges of the sensing electrodes RE. The driving signals may have driving pulses.

When the touch electrodes TE and RE are driven in a self-capacitance sensing scheme, the driving signals may be supplied to the driving electrodes TE as well as to the sensing electrodes RE through the first driving lines TL1, the second driving lines TL2, and the sensing lines RL. By doing so, the self capacitances of the driving electrodes TE and the sensing electrodes RE are charged. Changes in the amount of the charges of the self-capacitances of the driving electrodes TE and the sensing electrodes RE are measured through the first driving lines TL1, the second driving lines TL2, and the sensing lines RL, and it is determined whether a touch input is made based on the changes in the amount of the charges of the self-capacitances.

The driving electrodes TE, the sensing electrodes RE, and the connection electrodes BE may be formed as mesh-shaped electrodes as shown in FIG. 4. If the touch sensor layer TSL including the driving electrodes TE and the sensing electrodes RE is formed directly on the thin-film encapsulation layer TFEL as shown in FIG. 2, the distance between the second electrode of the emission material layer EML and the driving electrodes TE or the sensing electrodes RE of the touch sensor layer TSL may be close. As a result, a very large parasitic capacitance may be formed between the second electrode of the emission material layer EML and the driving electrodes TE or the sensing electrodes RE of the touch sensor layer TSL. For this reason, in order to reduce the parasitic capacitance, the driving electrodes TE and the sensing electrodes RE may be formed as the mesh-shaped pattern as shown in FIG. 4, rather than being formed as non-patterned electrodes of a transparent oxide conductive layer such as ITO and IZO.

A first guard line GL1 may be disposed on an outer side of the outermost one of the sensing lines RL. A first ground line GRL1 may be disposed on an outer side of the first guard line GL1. For example, in a plan view, the first guard line GL1 may be disposed on the right side of the rightmost one of the sensing lines RL, and the first ground line GRL1 may be disposed on the right side of the first guard line GL1.

A second guard line GL2 may be disposed between the innermost one of the sensing lines RL and a first driving line TL1 which is the rightmost one of the first driving lines TL1. The second guard line GL2 may be disposed between the rightmost one of the first driving lines TL1 and a second ground line GRL2. A third guard line GL3 may be disposed between the innermost one of the sensing lines RL and the second ground line GRL2. The second ground line GRL2 may be connected to the leftmost one of the first touch pads TP1 and the rightmost one of the second touch pads TP2.

A fourth guard line GL4 may be disposed on an outer side of the outermost one of the second driving lines TL2. A third ground line GRL3 may be disposed on an outer side of the fourth guard line GL4. For example, in a plan view, the fourth guard line GL4 may be disposed on the left and upper sides of the leftmost and the uppermost one of the second driving lines TL2, and the third ground line GRL3 may be disposed on the left and the upper sides of the fourth guard line GL4.

A fifth guard line GL5 may be disposed on an inner side of the innermost one of the second driving lines TL2. For example, in a plan view, the fifth guard line GL5 may be disposed between the rightmost one of the second driving lines TL2 and the touch electrodes TE and RE.

According to the embodiment shown in FIG. 4, the first ground line GRL1, the second ground line GRL2, and the third ground line GRL3 are respectively disposed on the uppermost side, the leftmost side, and the rightmost side of the display panel 100, as determined by the first direction DR1 and the second direction DR2 as shown therein. A ground voltage is applied to the first ground line GRL1, the second ground line GRL2, and the third ground line GRL3. Accordingly, when static electricity is applied from the outside, the static electricity can be discharged to the first ground line GRL1, the second ground line GRL2, and the third ground line GRL3.

According to the embodiment shown in FIG. 4, the first guard line GL1 is disposed between the outermost one of the sensing lines RL and the first ground line GRL1, so that it can reduce the influence by a change in the voltage of the first ground line GRL1 on the outermost one of the sensing lines RL. The second guard line GL2 is disposed between the innermost one of the sensing lines RL and the rightmost one of the first driving line TL1. Therefore, the second guard line GL2 can reduce the influence by a change in the voltage on the innermost one of the sensing lines RL and on the rightmost one of the first driving lines TL1. The third guard line GL3 is disposed between the innermost one of the sensing lines RL and the second ground line GRL2, so that it can reduce the influence by a change in the voltage of the second ground line GRL2 on the innermost one of the sensing lines RL. The fourth guard line GL4 is disposed between the outermost one of the second driving lines TL2 and the third ground line GRL3, so that it can reduce the influence by a change in the voltage of the third ground line GRL3 on the second driving line TL2. The fifth guard line GL5 is disposed between the innermost one of the second driving lines TL2 and the touch electrodes TE and RE, so that it can reduce mutual influence between the innermost one of the second driving lines TL2 and the touch electrodes TE and RE.

When the touch electrodes TE and RE are driven by a mutual-capacitance sensing scheme, a ground voltage may be applied to the first guard line GL1, the second guard line GL2, the third guard line GL3, the fourth guard line GL4, and the fifth line GL5. When the touch electrodes TE and RE are driven by a self-capacitance sensing scheme, the same driving signals as the driving signals applied to the first driving lines TL1, the second driving lines TL2, and the sensing lines RL may be applied to the first guard line GL1, the second guard line GL2, the third guard line GL3, the fourth guard line GL4, and the fifth guard line GL5.

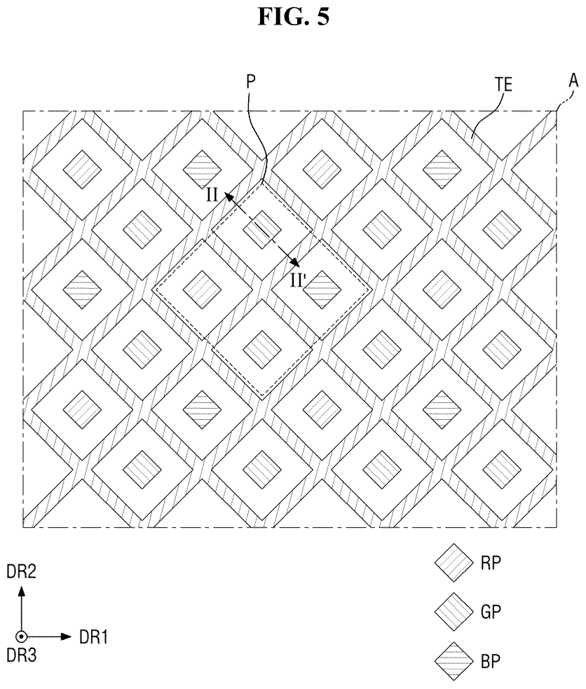

FIG. 5 is an enlarged schematic plan view of area A of FIG. 4.

FIG. 5 shows an example of the pixels of FIG. 3 and the touch sensor layer of FIG. 4.

Referring to FIG. 5, each pixel P may include sub-pixels. The sub-pixels may include first sub-pixels RP, second sub-pixels GP, and third sub-pixels BP. Each of the first sub-pixels RP may represent a first color, each of the second sub-pixels GP may represent a second color, and each of the third sub-pixels BP may represent a third color. The first color may be red, the second color may be green, and the third color may be blue. However, the disclosure is not limited thereto.

In the display panel 100, each of the pixels P may represent a white grayscale. One first sub-pixel RP, two second sub-pixels GP, and one third sub-pixel BP may be defined as one pixel P. A first sub-pixel RP, second sub-pixels GP, and a third sub-pixel BP, which are defined as a single pixel P, may be arranged in a diamond configuration as shown in FIG. 5.

The number of the first sub-pixels RP may be equal to the number of the third sub-pixels BP in the display panel 100. The number of the second sub-pixels GP in the display panel 100 may be equal to twice the number of the first sub-pixels RP or twice the number of the third sub-pixels BP. For example, in the display panel 100, the number of the second sub- pixels GP may be equal to a sum of the number of the first sub-pixels RP and the number of the third sub-pixels BP.

In FIG. 5, the first sub-pixels RP, the second sub-pixels GP, and the third sub-pixels BP are formed in a diamond configuration in a plan view. However, the disclosure is not limited thereto. For example, the first sub-pixels RP, the second sub-pixels GP, and the third sub-pixels BP may be formed in a rectangular configuration or a square configuration, or they may be formed in any other polygonal configuration, a circular configuration, or an elliptic configuration, other than a quadrangular configuration. In an embodiment, the first sub-pixels RP, the second sub-pixels GP, and the third sub-pixels BP may have different shapes.

In FIG. 5, the first sub-pixels RP, the second sub-pixels GP, and the third sub-pixels BP have a same size in a plan view. However, the disclosure is not limited thereto. For example, the first sub-pixels RP, the second sub-pixels GP, and the third sub-pixels BP may have different sizes from one another in a plan view. For example, in a plan view, a size of the first sub-pixels RP may be larger than a size of the second sub-pixels GP, and a size of the third sub-pixels BP may be larger than a size of the second sub-pixels GP. For example, in a plan view, a size of the first sub-pixels RP may be substantially equal to or smaller than a size of the third sub-pixels BP.

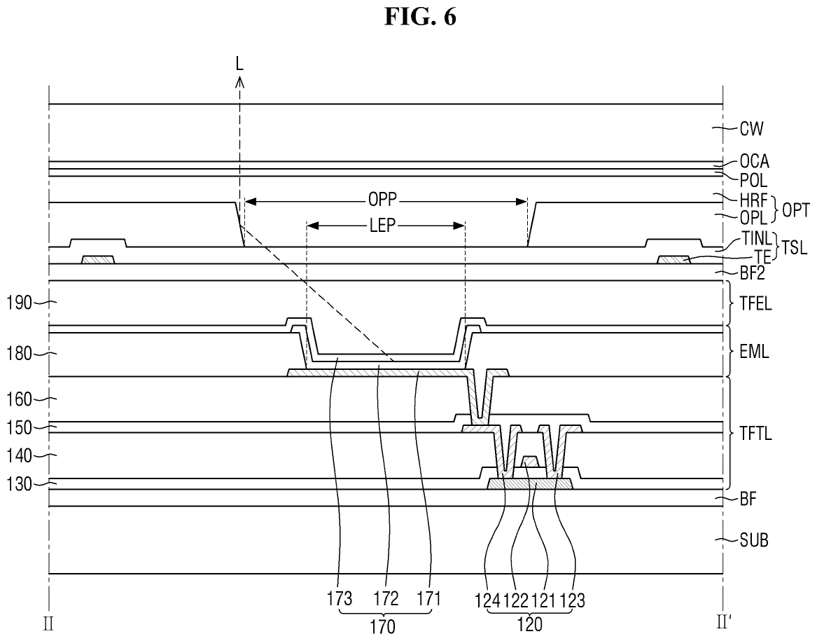

The driving electrodes TE may surround the first sub-pixels RP, the second sub-pixels GP, and the third sub-pixels BP in a plan view. The driving electrodes TE may be formed in a mesh-shaped pattern and disposed between the sub pixels RP, GP, and BP. By doing so, it may be possible to prevent the emission area of each of the sub-pixels RP, GP, and BP from being reduced due to the driving electrodes TE. Since an overlapping area between the driving electrode TE and the second electrode 173 can be reduced (see FIG. 6), the parasitic capacitance between the driving electrodes TE and the second electrode 173 can be reduced. The sensing electrodes RE may be formed to be substantially the same as the driving electrodes TE; and, therefore, the description on the sensing electrode RE will be omitted.

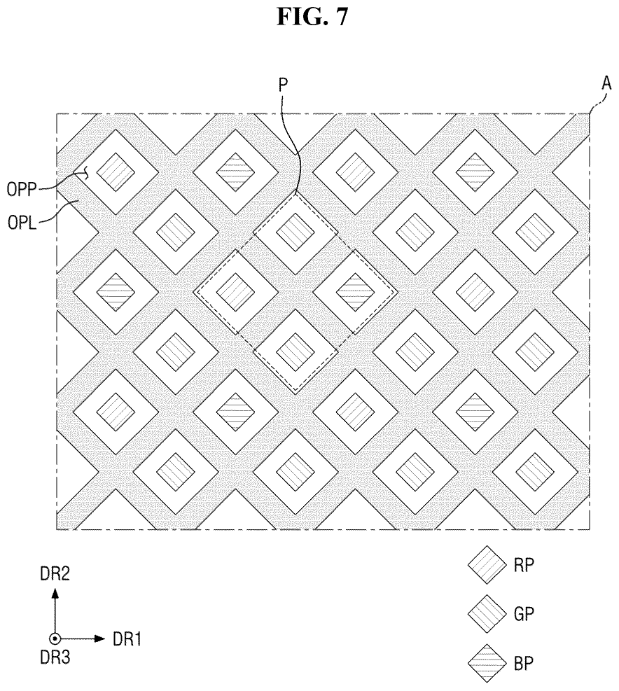

FIG. 6 is a schematic cross-sectional view taken along line II-II′ of FIG. 5. FIG. 7 is an enlarged schematic plan view of the first planarization layer and the sub-pixels in area A of FIG. 4.

Referring to FIGS. 6 and 7, the thin-film transistor layer TFTL may be disposed on the substrate SUB. The thin-film transistor layer TFTL may include thin-film transistors 120, a gate insulating film 130, an interlayer dielectric film 140, a protective film 150, and a planarization film 160.

For example, a first buffer film BF may be disposed on a surface of the substrate SUB. The first buffer film BF may be formed on the surface of the substrate SUB in order to protect the thin-film transistors 120 and an organic emitting layer 172 of the emission material layer EML from moisture that may permeate through the substrate SUB. The first buffer film BF may include multiple inorganic films alternately stacked on one another. For example, the first buffer film BF may be formed as a stack of multiple films in which one or more inorganic films of silicon oxide (SiNₓ), silicon oxynitride (SiNₓO_{y}), silicon oxide (SiOₓ), titanium oxide (TiO₂), and aluminum oxide (Al₂O₃) are stacked on one another alternately. However, embodiments are not limited thereto, and the first buffer film BF may be omitted.

The thin-film transistor 120 may be disposed on the first buffer film BF. Each thin- film transistor 120 includes an active layer 121, a gate electrode 122, a source electrode 123, and a drain electrode 124. In FIG. 6, the thin-film transistor 120 is implemented as a top-gate transistor in which the gate electrode 122 is located above the active layer 121. However, the disclosure is not limited thereto. For example, the thin-film transistor 120 may be implemented as a bottom-gate transistor in which the gate electrode 122 is located below the active layer 121, or as a double-gate transistor in which gate electrodes 122 are disposed above and below the active layer 121.

The active layer 121 may be disposed on the first buffer film BF. The active layer 121 may include polycrystalline silicon, single crystal silicon, low-temperature polycrystalline silicon, amorphous silicon, or an oxide semiconductor. The oxide semiconductor layer may include, for example, a binary compound (ABₓ), a ternary compound (ABₓC_{y}), or a quaternary compound (ABₓC_{y}D_{z}) containing indium (In), zinc (Zn), gallium (Ga), tin (Sn), titanium (Ti), aluminum (Al), hafnium (Hf), zirconium (Zr), magnesium (Mg), etc. For example, the active layer 121 may include an oxide including indium, tin, and zinc (ITZO), or an oxide including indium, gallium, and zinc (IGZO). A light-blocking layer (not shown) for blocking external light incident on the active layer 121 may be further disposed between the first buffer film BF and the active layer 121.

The gate insulating film 130 may be disposed on the active layer 121. The gate insulating film 130 may include at least one of silicon oxide (SiNₓ), silicon oxynitride (SiNₓO_{y}), silicon oxide (SiOₓ), titanium oxide (TiO₂), and aluminum oxide (Al₂O₃).

The gate electrode 122 may be disposed on the gate insulating film 130. The gate electrode 122 may be formed of a single layer or multiple layers of one of molybdenum (Mo), aluminum (Al), chromium (Cr), gold (Au), titanium (Ti), nickel (Ni), neodymium (Nd), copper (Cu), or an alloy thereof. Although not shown in the drawings, a gate line may be disposed on a same layer as the gate electrode 122.

The interlayer dielectric film 140 may be disposed on the gate electrode 122. The interlayer dielectric film 140 may include at least one of silicon oxide (SiNₓ), silicon oxynitride (SiNₓO_{y}), silicon oxide (SiOₓ), titanium oxide (TiO₂), and aluminum oxide (Al₂O₃).

The source electrode 123 and the drain electrode 124 may be disposed on the interlayer dielectric film 140. Each of the source electrode 123 and the drain electrode 124 may be connected to the active layer 121 through contact holes penetrating through the gate insulating film 130 and the interlayer dielectric film 140. The source electrode 123 and the drain electrode may be formed of a single layer or multiple layers of one of molybdenum (Mo), aluminum (Al), chromium (Cr), gold (Au), titanium (Ti), nickel (Ni), neodymium (Nd), copper (Cu), or an alloy thereof.

The protective film 150 may be formed on the source electrode 123 and the drain electrode 124 in order to insulate the thin-film transistors 120. The protective film 150 may include at least one of silicon oxide (SiNₓ), silicon oxynitride (SiNₓO_{y}), silicon oxide (SiOₓ), titanium oxide (TiO₂), and aluminum oxide (Al₂O₃).

The planarization film 160 may be formed on the protective film 150 to provide a flat surface over the step differences of the thin-film transistor 120. The planarization film 160 may include an acryl resin, an epoxy resin, a phenolic resin, a polyamide resin, a polyimide resin, etc.

The emission material layer EML may be disposed on the thin-film transistor layer TFTL. The emission material layer EML may include a light-emitting element 170 and a pixel-defining film 180.

The light-emitting element 170 and the pixel-defining film 180 may be disposed on the planarization film 160. The light-emitting element 170 may include a first electrode 171, an organic emitting layer 172, and a second electrode 173.

The first electrode 171 may be disposed (for example, directly disposed) on the planarization film 160. The first electrode 171 may be electrically connected to the source electrode 123 of the thin-film transistor 120 through a contact hole penetrating through the protective film 150 and the planarization film 160.

In a top-emission organic light-emitting diode where the emitted light exits from the organic emitting layer 172 toward the second electrode 173, the first electrode 171 may be formed of a metal material having a high reflectivity such as a stack structure of aluminum and titanium (Ti/Al/Ti), a stack structure of aluminum and ITO (ITO/Al/ITO), an APC alloy, and a stack structure of APC alloy and ITO (ITO/APC/ITO). The APC alloy is an alloy of silver (Ag), palladium (Pd), and copper (Cu).

In a bottom-emission organic light-emitting diode where the emitted light exits from the organic emitting layer 172 toward the first electrode 171, the first electrode 171 may be formed of a transparent conductive material (TCP) such as ITO and IZO that can transmit light, or a semi-transmissive conductive material such as magnesium (Mg), silver (Ag), and an alloy of magnesium (Mg) and silver (Ag). When the first electrode 171 is formed of a semi-transmissive conductive material, light extraction efficiency can be increased by using microcavities.

The pixel-defining film 180 may separate first electrodes 171 from one another on the planarization film 160 in order to define the sub-pixels RP, GP, and BP. The pixel-defining film 180 may cover an edge of the first electrode 171. The pixel-defining film 180 may be formed of an organic layer such as an acryl resin, an epoxy resin, a phenolic resin, a polyamide resin, or a polyimide resin.

In each of the sub-pixels RP, GP, and BP, the first electrode 171, the organic emitting layer 172, and the second electrode 173 are stacked on one another sequentially, so that holes from the first electrode 171 and electrons from the second electrode 173 combine with each other in the organic emitting layer 172 to emit light. The sub-pixels RP, GP, and BP may each include a light-emitting element 170.

The organic emitting layer 172 may be disposed on the first electrode 171 and the pixel-defining film 180. The organic emitting layer 172 may include an organic material and may emit light of a particular color. For example, the organic emitting layer 172 may include a hole transporting layer, an organic material layer, and an electron transporting layer. For example, the organic emitting layer 172 of the first sub-pixel RP may emit light of the first color, the organic emitting layer 172 of the second sub-pixel GP may emit light of the second color, and the organic emitting layer 172 of the third sub-pixel BP may emit light of the third color. The first color may be red, the second color may be green, and the third color may be blue. However, the disclosure is not limited thereto.

In another embodiment, the organic emitting layer 172 of each of the sub-pixels RP, GP, and BP may emit white light. For example, the first sub-pixel RP may emit light of the first color through a color filter that transmits the light of the first color, the second sub-pixel GP may emit light of the second color through a color filter that transmits the light of the second color, and the third sub-pixel BP may emit light of the third color through a color filter that transmits the light of the third color.

The second electrode 173 may be disposed on the organic emitting layer 172. The second electrode 173 may cover the organic emitting layer 172. The second electrode 173 may be a common layer formed across the sub-pixels RP, GP, and BP.

In a top-emission organic light-emitting diode, the second electrode 173 may be formed of a transparent conductive material (TCP) such as ITO and IZO that can transmit light, or a semi-transmissive conductive material such as magnesium (Mg), silver (Ag), and an alloy of magnesium (Mg) and silver (Ag). When the second electrode 173 is formed of a semi-transmissive conductive material, light extraction efficiency can be increased by using microcavities.

In a bottom-emission organic light-emitting diode, the second electrode 173 may be formed of a metal material having a high reflectivity such as a single layer of aluminum, a stack structure of aluminum and titanium (Ti/Al/Ti), a stack structure of aluminum and ITO (ITO/Al/ITO), an APC alloy, and a stack structure of APC alloy and ITO (ITO/APC/ITO). The APC alloy is an alloy of silver (Ag), palladium (Pd), and copper (Cu).

The thin-film encapsulation layer TFEL may be disposed on the emission material layer EML. The thin-film encapsulation layer TFEL may include an encapsulation film 190.

The encapsulation film 190 may be disposed on the second electrode 173. The encapsulation layer 190 may include at least one inorganic layer to prevent oxygen and/or moisture from permeating into the organic emitting layer 172 and the second electrode 173. The encapsulation layer 190 may include at least one organic layer to protect the light-emitting element layer EML from foreign substances such as dust. For example, the encapsulation layer 190 may include a first inorganic layer disposed on the second electrode 173, an organic layer disposed on the first inorganic layer, and a second inorganic layer disposed on the organic layer. The first inorganic film and the second inorganic film may each independently include, but is not limited to, silicon oxide (SiNₓ), silicon oxynitride (SiNₓO_{y}), silicon oxide (SiOₓ), titanium oxide (TiO₂), or aluminum oxide (Al₂O₃). The organic film may include, but is not limited to, an acryl resin, an epoxy resin, a phenolic resin, a polyamide resin, a polyimide resin, etc.

A second buffer film BF2 may be disposed on the encapsulation layer TFEL. The second buffer film BF2 may be formed of multiple inorganic layers stacked on one another. For example, the second buffer film BF2 may be formed as a stack of multiple films in which one or more inorganic films of silicon oxide (SiNₓ), silicon oxynitride (SiNₓO_{y}), silicon oxide (SiOₓ), titanium oxide (TiO₂), or aluminum oxide (Al₂O₃) are stacked on one another alternately.

The touch sensor layer TSL is formed on the second buffer film BF2. As shown in FIG. 4, the touch sensor layer TSL may include the driving electrodes TE, the sensing electrodes RE, the connection electrodes BE, the first driving lines TL1, the second driving lines TL2, the sensing lines RL, the guard lines GL1, GL2, GL3, GL4, and GL5, and the ground lines GRL1, GRL2, and GRL3. FIG. 6 shows only the driving electrodes TE of the touch sensor layer TSL for convenience of illustration.

The driving electrodes TE may be disposed on the second buffer film BF2. The sensing electrodes RE, the first driving lines TL1, the second driving lines TL2, the sensing lines RL, the guard lines GL1, GL2, GL3, GL4, and GL5, and the ground lines GRL1, GRL2, and GRL3 may be disposed on the encapsulation film 190, in addition to the driving electrodes TE. For example, the driving electrodes TE, the sensing electrodes RE, the first driving lines TL1, the second driving lines TL2, the sensing lines RL, the guard lines GL1, GL2, GL3, GL4, and GL5, and the ground lines GRL1, GRL2, and GRL3, except the connection electrodes BE, may be disposed on a same layer and may be made of a same material. The driving electrodes TE, the sensing electrodes RE, the first driving lines TL1, the second driving lines TL2, the sensing lines RL, the guard lines GL1, GL2, GL3, GL4, and GL5 and the ground lines GRL1, GRL2, and GRL3 may each be made of, but are not limited to, a stack structure of aluminum and titanium (Ti/Al/Ti), a stack structure of aluminum and ITO (ITO/Al/ITO), an APC alloy, or a stack structure of an APC alloy and ITO (ITO/APC/ITO).

A touch insulating film TINL may be disposed on the driving electrodes TE. The touch insulating film TINL may include, but is not limited to, silicon oxide (SiNₓ), silicon oxynitride (SiNₓO_{y}), silicon oxide (SiOₓ), titanium oxide (TiO₂), or aluminum oxide (Al₂O₃).

Although not shown in the drawings, the connection electrodes BE shown in FIG. 4 may be disposed on the touch insulating film TINL. Each of the connection electrodes BE may be connected to the driving electrodes TE through a contact hole penetrating the touch insulating film TINL. The driving electrodes TE arranged in the second direction DR2 may be electrically connected to each other by the connection electrodes BE. The connection electrodes BE may be formed of, but is not limited to, a stack structure of aluminum and titanium (Ti/Al/Ti), a stack structure of aluminum and ITO (ITO/Al/ITO), an APC alloy, or a stack structure of an APC alloy and ITO (ITO/APC/ITO).

The optical layer OPT is disposed on the touch sensor layer TSL. The optical layer OPT may completely reflect light which is emitted from the sub-pixels RP, GP, and BP and travels toward a side surface rather than in the third direction DR3 so that the light travels in the third direction DR3. The optical layer OPT may include a first planarization layer OPL and a second planarization layer HRF.

The first planarization layer OPL may be disposed on the touch insulating film TINL. The first planarization layer OPL overlaps the pixel-defining film 180 but may not overlap the sub-pixels RP, GP, and BP. The first planarization layer OPL may include an opening portion OPP overlapping an emission area LEP of each of the sub-pixels RP, GP, and BP.

The first planarization layer OPL may be formed so that side surfaces forming the inner circumferential surface of the opening portion OPP have a taper angle. This taper angle may be formed as a normal taper. The first planarization layer OPL may be formed of, but is not limited to, an acryl resin, an epoxy resin, a phenolic resin, a polyamide resin, a polyimide resin, etc.

The second planarization layer HRF may be disposed over the touch insulating film TINL and the first planarization layer OPL. The second planarization layer HRF provides a flat surface over the opening portion OPP of the first planarization layer OPL which has different heights. To this end, a thickness of the second planarization layer HRF may be larger than a thickness of the first planarization layer OPL. The opening portion OPP of the first planarization layer OPL may be filled with the second planarization layer HRF in a shape like a lens that is disposed upside down. Such a lens shape of the second planarization layer HRF may reflect light at an interface with the first planarization layer OPL and may propagate the light in the third direction DR3.

The second planarization layer HRF may be formed as an organic film. The second planarization layer HRF may include a transparent material having excellent coating properties and excellent mechanical properties. The second planarization layer HRF will be described in detail later.

Light emitted from the emission area LEP of each of the sub-pixels RP, GP, and BP may be reflected off a side surface of the second planarization layer HRF, which is a portion of an interface between the first planarization layer OPL and the second planarization layer HRF, and may travel in the third direction DR3. To this end, a refractive index of the second planarization layer HRF may be greater than a refractive index of the first planarization layer OPL. For example, a refractive index of the second planarization layer HRF may be greater than a refractive index of the first planarization layer OPL by 0.05 or more. The refractive index of the second planarization layer HRF may be in a range of about 1.58 to about 1.65. For example, the refractive index of the second planarization layer HRF may be in a range of about 1.6 to about 1.63.

Light L which is output from the sub-pixels RP, GP, and BP and travels toward a side surface may be completely reflected off a side surface of the second planarization layer HRF and travel in the third direction DR3. In this manner, it is possible to increase the output efficiency of light from the sub-pixels RP, GP, and BP, thereby increasing the lifespan of the organic light-emitting diodes. Thus, it is possible to save power consumption of the organic light-emitting diode display.

A polarizing plate POL, an adhesive member OCA, and a cover window CW may be disposed on the optical layer OPT.

The polarizing plate POL may be disposed on the second planarization layer HRF of the optical layer OPT. The polarizing plate POL can reduce the reflectance of external light incident from the outside to improve display quality.

The cover window CW may be attached on the polarizing plate POL by the adhesive member OCA. The cover window CW can prevent the underlying elements from being damaged by an external physical force. The adhesive member OCA may attach the cover window CW to the polarizing plate POL, and may be transparent.

The second planarization layer HRF of the display device 10 described above may be applied on the substrate SUB via a solution process such as inkjet printing. As described above, the second planarization layer HRF may have a higher refractive index than the first planarization layer OPL. In case that the second planarization layer HRF contains inorganic nanoparticles having a high refractive index, such as ZrOx particles, light scattering and reflection may increase and light may be reflected downward, which may decrease output efficiency. Inorganic nanoparticles that are distributed in the second planarization layer HRF may be concentrated on the surface, and thus the refractive index may become non-uniform between the surface and the inner region. As a result, mechanical properties may be deteriorated.

In view of the above, embodiments provide a second planarization layer HRF that does not contain inorganic nanoparticles and that has a higher refractive index than the first planarization layer HRF by 0.05 or more.

According to embodiments, the second planarization layer HRF may be formed of a coating composition including a first monomer, a second monomer, a photoinitiator, a surfactant, and a solvent. The coating composition may be prepared by mixing a solid a solid content that includes the first monomer, the second monomer, the photoinitiator, and the surfactant, with the solvent.

The first monomer can increase the transmittance and the refractive index of the second planarization layer HRF. The first monomer may include an acrylate monomer. For example, the first monomer may include an acrylate monomer having a conjugated structure including two benzene rings.

The first monomer may be represented by Chemical Formula 1 or Chemical Formula 2:

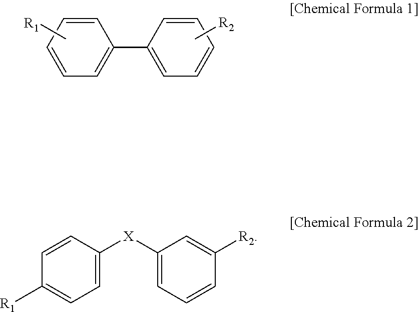

In Chemical Formula 1 and Chemical Formula 2,
R₁ and R₂ may each independently be hydrogen,

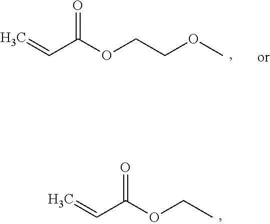

and
X may be O or S.

In an embodiment, in Chemical Formula 1 and Chemical Formula 2, at least one of R₁ and R₂ may each independently be

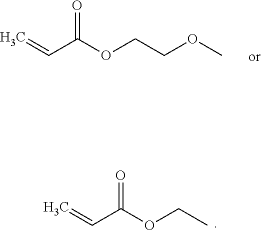

The monomer represented by Chemical Formula 1 or Chemical Formula 2 may include a conjugated monofunctional acrylate or a conjugated bifunctional acrylate.

In an embodiment, a conjugated monofunctional acrylate represented by Chemical Formula 1 or Chemical Formula 2 may be represented by one of the following formulas:

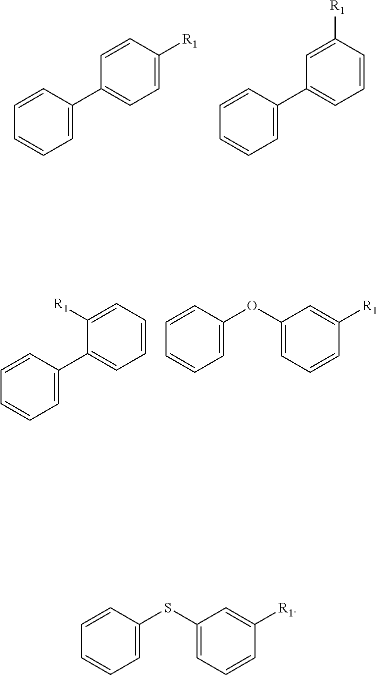

In the formulas above, R₁ may be

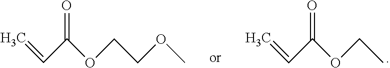

In an embodiment, the conjugated monofunctional acrylate may be the following biphenylmethyl acrylate:

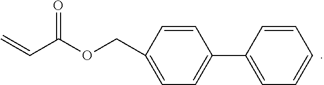 [SMILES: C=CC(=O)OCc1ccc(-c2ccccc2)cc1]

In an embodiment, a conjugated bifunctional acrylate represented by Chemical Formula 1 or Chemical Formula 2 may be represented by one of the following formulas:

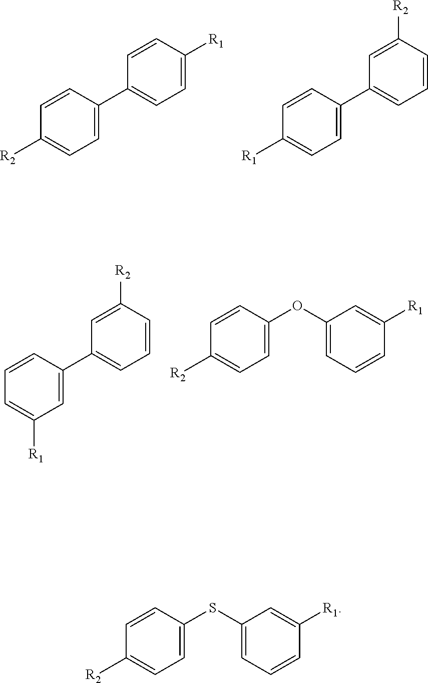

In the formulas above, R₁ and R₂ may each independently be hydrogen,

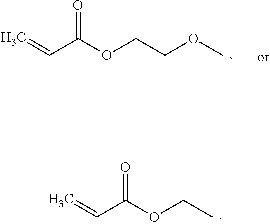

The above-described acrylate monomer having a conjugated structure containing two benzene rings has a high refractive index. As the coating composition for forming the second planarization layer HRF includes the acrylate monomer having a conjugated structure containing two benzene rings, a second planarization layer HRF having a high refractive index can be formed.

A content of the first monomer may be in a range of about 50 wt % to about 90 wt %, per 100 wt % of the solid content of the coating composition. Within the ranges above, the refractive index of the coating composition can be increased.

The second monomer may lower the viscosity of the coating composition of the second planarization layer HRF. The second monomer may include an acrylate monomer. For example, the second monomer may include a bifunctional acrylate monomer. The viscosity of the coating composition can be lowered by using a monomer having a viscosity of 10 cp or less as the bifunctional acrylate monomer.

In an embodiment, the second monomer may include a polyethylene glycol diacrylate or a diol diacrylate. For example, the polyethylene glycol diacrylate may be represented by the formula below:

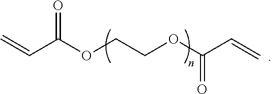

In the formula above, n may be an integer from one to ten.

For example, the diol diacrylate may be represented by the formula below:

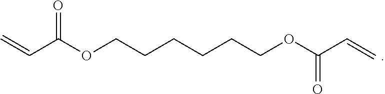 [SMILES: C=CC(=O)OCCCCCCOC(=O)C=C]

The above-described bifunctional acrylate monomer has a low viscosity. In an embodiment, the bifunctional acrylate monomer has a viscosity of 10 cp or less, thereby lowering the overall viscosity of the coating composition to improve coating properties.

A content of the second monomer may be in a range of about 5 wt % to about 40 wt %, per 100 wt % of the solid content of the coating composition. Within the ranges above, the viscosity of the coating composition can be lowered.

The photoinitiator may include an oxime-based compound, an acetophenone-based compound, a thioxanthone-based compound, a benzophenone-based compound, or a combination thereof.

The oxime-based compound may include, for example, 1,2-octanedione, 2-dimethylamino-2-(4-methylbenzyl)-1-(4-morpholin-4-yl-phenyl)-butan-1-one, 1-(4-phenylsulfanyl) phenyl)-butane-1,2-dione-2-oxime-O-benzoate, 1-(4-phenylsulfanylphenyl)-octane-1,2-dione-2-oxime-O-benzoate, 1-(4-phenylsulfanylphenyl)-octane-1-oneoxime-O-acetate, 1-(4-phenylsulfanylphenyl)-butan-1-one-2-oxime-O-acetate, 2-(O-benzoyloxime)-1-[4-(phenylthio)phenyl]-1,2-octandione, 1-(O-acetyloxime)-1-[9-ethyl-6-(2-methylbenzoyl)-9H-carbazol-3-yl]ethanone, O-ethoxycarbonyl-α-oxyamino-1-phenylpropan-1-one, or a combination thereof.

The acetophenone-based compound may include, for example, 4-phenoxy dichloroacetophenone, 4-t-butyl dichloroacetophenone, 4-t-butyl trichloroacetophenone, 2,2-diethoxyacetophenone, 2-hydroxy-2-methyl-1-phenyl-propane -1-one, 1-(4-isopropylphenyl)-2-hydroxy-2-methyl-propan-1-one, 1-(4-dodecylphenyl)-2-hydroxy-2-methylpropan-1-one, 4-(2-hydroxyethoxy)-phenyl-(2-hydroxy-2-propyl) ketone, 1-hydroxy cyclohexyl phenyl ketone and 2-methyl-1-[4-(methylthio)phenyl]-2-morpholino-propan-1-one, or a combination thereof.

The thioxanthone-based compound may include, for example, thioxanthone, 2-chlorothioxanthone, 2-methylthioxanthone, isopropyl thioxanthone, 2,4-diethyl thioxanthone, 2,4-diisopropyl thioxanthone, or a combination thereof.

The benzophenone-based compound may include, for example, benzophenone, benzoyl benzoic acid, benzoyl benzoic acid methyl ester, 4-phenyl benzophenone, hydroxybenzophenone, 4-benzoyl-4′-methyl diphenyl sulfide, 3,3′-dimethyl-4-methoxy benzophenone, or a combination thereof.

A content of the photoinitiator may be in a range of about 0.1 wt % to about 10 wt %, per 100 wt % of the solid content of the coating composition. Within the ranges above, photopolymerization may sufficiently occur during exposure of the coating composition.

The surfactant may work as a coupling agent while improving adhesion between the coating composition and the substrate.

The surfactant may include one or more of anionic surfactants, cationic surfactants, amphoteric surfactants, and nonionic surfactants.

The anionic surfactant may include at least one selected from the group consisting of: alkyl sulfonic acid (sulfonate), alkyl sulfuric acid (sulfate), aralkyl and alkaryl anionic surfactants, alkyl succinic acid (succinate) and alkyl sulfosuccinates (sulfo succinate). For example, the anionic surfactant may include at least one salt among sodium, magnesium, ammonium, monoethanolamine, diethanolamine and triethanolamine salts of alkaryl sulfonic acid, alkyl sulfonic acid or alkaryl sulfonic acid.

The cationic surfactant may include an amine salt or an ammonium salt derivative. The amine salt-based cationic surfactant may include polyoxyethylene alkylamine. The quaternary alkyl ammonium-based cationic surfactant may include tetraalkylammonium or pyridinium salt. The quaternary ammonium-based cationic surfactant may include, for example, at least one selected from the group consisting of: alkyltrimethylammonium salts such as cetyltrimethylammonium bromide (CTAB), hexadecyltrimethylammonium bromide, cetyltrimethylammonium chloride (CTAC), cetylpyridinium chloride (CPC), benzalkonium chloride (BAC), benzetonium chloride (BZT), 5-bromo-5-nitro-1,3-dioxane, dimethyldioctadecylammonium chloride, anddioctadecylmethylammonium bromide (DODAB).

The amphoteric surfactant may include at least one selected from the group consisting of: cocoampocarboxyglycinate, cocoampocarboxypropionate, cocobetaine, N-cocoamidopropyldimethylglycine and N-lauryl-N-carboxymethyl-N-(2-hydroxyethyl)ethylenediamine. The amphoteric surfactant may include at least one selected from the group consisting of: quaternary cycloimidates, betaines such as α-(tetradecyldimethylammonio) acetate, beta-(hexadecyldiethylammonio) propionate and gamma-(dodecyldimethylammonio) butyrate.

The nonionic surfactants may include one or more of fatty acid alkanol amides or amine oxide surfactants. The fatty acid alkanol amide may be a nonionic surfactant obtained by the reaction of alkanolamine such as monoethanolamine, diethanolamine, monoisopropanolamine and diisopropanolamine with fatty acid or fatty acid ester to form amide. The fatty acid alkanol amide surfactant may include, for example, at least one selected from the group consisting of: diethanolamide, isostearic acid diethanolamide, lauric acid diethanolamide, capric acid diethanolamide, coconut fatty acid diethanolamide, linoleic acid diethanolamide, myristic acid diethanolamide, oleic acid diethanolamide, stearic acid diethanolamide, monoethanolamide, coconut fatty acid monoethanolamide, oleic acid monoisopropanolamide and lauric acid monoisopropanolamide.

The surfactant may include a silicone-based surfactant. A silicone-based surfactant has the benefit of providing excellent adhesion to the substrate on which the coating composition is coated.

As the silicone-based surfactant, for example, a copolymer of organosiloxane or dimethylpolysiloxane modified with polyether may be used. It should be understood, however, that the disclosure is not limited thereto. Any silicone-based surfactant of the related art may be used.

A content of the surfactant may be in a range of about 0.1 wt % to about 10 wt %, per 100 wt % of the solid content of the coating composition. Within the ranges above, the interfacial adhesion of the second planarization layer HRF formed of the coating composition can be improved.

The solvent may be a material that is compatible with the first monomer and the second monomer but does not react with them.

The solvent may be a compound, for example, alcohols such as methanol and ethanol; ethers such as dichloroethyl ether, n-butyl ether, diisoamyl ether, methylphenyl ether and tetrahydrofuran; glycol ethers such as ethylene glycol methyl ether, ethylene glycol ethyl ether and propylene glycol methyl ether; cellosolve acetates such as methyl cello solve acetate, ethyl cellosolve acetate and diethyl cellosolve acetate; carbitols such as methylethyl carbitol, diethyl carbitol, diethylene glycol monomethyl ether, diethylene glycol monoethyl ether, diethylene glycol dimethyl ether, diethylene glycol methyl ethyl ether and diethylene glycol diethyl ether; propylene glycol alkyl ether acetates such as propylene glycol methyl ether acetate, propylene glycol monoethyl ether acetate and propylene glycol propyl ether acetate; aromatic hydrocarbons such as toluene and xylene; ketones such as methyl ethyl ketone, cyclohexanone, 4-hydroxy-4-methyl-2-pentanone, methyl-n-propyl ketone, methyl-n-butyl kenone, methyl-n-amyl ketone, and 2-heptanone; saturated aliphatic monocarboxylic acid alkyl esters such as ethyl acetate, n-butyl acetate and isobutyl acetate; lactic acid alkyl esters such as methyl lactate and ethyl lactate; hydroxyacetic acid alkyl esters such as methyl hydroxyacetate, ethyl hydroxyacetate and butyl hydroxyacetate; acetic acid alkoxyalkyl esters such as methoxymethyl acetate, methoxyethyl acetate, methoxybutyl acetate, ethoxymethyl acetate and ethoxyethyl acetate; 3-hydroxypropionic acid alkyl esters such as methyl 3-hydroxypropionate and ethyl 3-hydroxypropionate; 3-alkoxypropionic acid alkyl esters such as methyl 3-methoxypropionate, ethyl 3-methoxypropionate, ethyl 3-ethoxypropionate and methyl 3-ethoxypropionate; 2-hydroxypropionic acid alkyl esters such as methyl 2-hydroxypropionate, ethyl 2-hydroxypropionate and propyl 2-hydroxypropionate; 2-alkoxypropionic acid alkyl esters such as methyl 2-methoxypropionate, ethyl 2-methoxypropionate, ethyl 2-ethoxypropionate and methyl 2-ethoxypropionate; 2-hydroxy-2-methylpropionic acid alkyl esters such as methyl 2-hydroxy-2-methylpropionate and ethyl 2-hydroxy-2-methylpropionate; 2-alkoxy-2-methylpropionic acid alkyl esters such as methyl 2-methoxy-2-methylpropionate and ethyl 2-ethoxy-2-methylpropionate; esters such as 2-hydroxyethyl propionate, 2-hydroxy-2-methylethyl propionate, hydroxyethyl acetate and methyl 2-hydroxy-3-methylbutanoate; or ketonic acid esters such as ethyl pyruvate. The solvent may include N-methylformamide, N,N-dimethylformamide, N-methylformanilide, N-methylacetamide, N,N-dimethylacetamide, N-methylpyrrolidone, dimethyl sulfoxide, benzylethyl ether, di-hexyl ether, acetylacetone, isophorone, caproic acid, caprylic acid, 1-octanol, 1-nonanol, benzyl alcohol, benzyl acetate, ethyl benzoate, diethyl oxalate, diethyl maleate, γ-butyrolactone, ethylene carbonate, propylene carbonate, phenyl cellosolve acetate, or a combination thereof.

According to another embodiment, the solvent may include glycol ethers such as ethylene glycol monoethyl ether; ethylene glycol alkyl ether acetates such as ethyl cellosolve acetate; esters such as 2-hydroxyethyl propionate; diethylene glycols such as diethylene glycol monomethyl ether; propylene glycol alkyl ether acetates such as propylene glycol monomethyl ether acetate and propylene glycol propyl ether acetate; or a combination thereof.

A content of the solvent may be in a range of about 50 wt % to about 90 wt %, per 100 wt % of the total coating composition. Within the ranges above, the coating composition has an appropriate viscosity to allow for improved processability. Thus, the solid content of the coating composition may be in a range of about 10 wt % to about 50 wt %, per 100 wt % of the total coating composition.

The coating composition according to embodiments may be formed into the second planarization layer HRF of FIG. 6 as described above. As the coating composition includes the first monomer having a high refractive index and the second monomer having a low viscosity, the refractive index of the second planarization layer HRF can be increased and coating properties can be improved.

Hereinafter, Examples and Experimental Examples for the coating composition according to embodiments will be described in detail.

### EXAMPLE 1

### Preparation of Coating Composition

For a basis of 100 wt % of a solid content, 60 wt % of a first monomer (biphenylmethyl acrylate), 30 wt % of a second monomer (polyethylene glycol diacrylate), 5 wt % of a photoinitiator (Irgacure 369), and 5 wt % of a surfactant (copolymer of dimethylpolysiloxane) were prepared. A coating composition was prepared by mixing the solid content in 80 wt % of a solvent per 100 wt % of the total coating composition.

### EXPERIMENTAL EXAMPLE 1

### Measurement of Refractive Index of Coating Film Versus Content of First Monomer

A coating film was formed by applying the coating composition prepared in Example 1 onto a glass substrate. Coating films were formed while increasing the content of the first monomer in the coating composition from 50 wt % to 90 wt % of a solid content, and the refractive index of each of the coating films was measured.

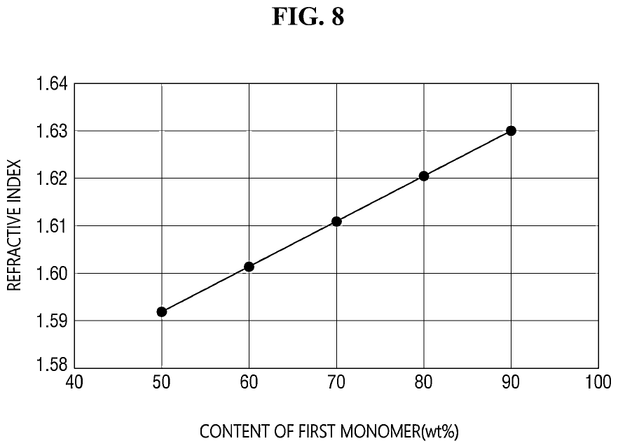

FIG. 8 is a graph showing the refractive index of the coating film versus the content of the first monomer in the coating composition.

Referring to FIG. 8, the refractive index of the coating film was approximately 1.59 when the content of the first monomer was 50 wt % of a solid content, and the refractive index of the coating film was approximately 1.63 when the content of the first monomer is 90 wt % of a solid content.

It can be seen that the refractive index of the coating film increases with the content of the first monomer in the coating composition.

The viscosity and the surface tension of the coating composition were measured in Example 1 and Experimental Example 1, and the refractive index, the modulus, and the elongation of the coating film were measured. Based on the above results, the coating composition and the coating film according to this embodiment can satisfy the following physical properties:
i) the refractive index of the coating film: 1.58 to 1.65
ii) the modulus (GPa) of the coating film: 0.1 to 1.5
iii) the elongation (%) of coating film: 5 or more
iv) the viscosity (cp) of the coating composition: 10 to 25
v) the surface tension (mN/m) of the coating composition: 22 to 30

### EXPERIMENTAL EXAMPLE 2

### Evaluation of Light Efficiency of Display Device

The display devices shown in FIG. 6 were fabricated. Display devices according to Sample #1 and Sample #2 were fabricated by forming the second planarization layer HRF (see FIG. 6) using coating compositions having refractive indices of 1.58 and 1.61, respectively. A display device according to the Comparative Example was fabricated by forming the second planarization layer using a high refractive index material having the refractive index of 1.6 including ZrO₂ inorganic particles.

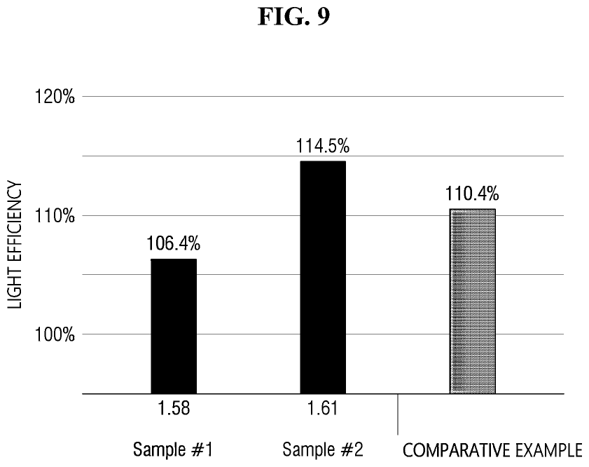

FIG. 9 is a graph showing results of measuring the light efficiencies of the display devices according to Samples #1 and #2 and the Comparative Example. In FIG. 9, a light efficiency of 100% is based on the light efficiency of a display device with no second planarization layer. Light efficiency may be a relative ratio of luminance values of display devices.

Referring to FIG. 9, Sample #1 exhibited a light efficiency of approximately 106.4%, and Sample #2 exhibited a light efficiency of approximately 114.5%. The Comparative Example exhibited a light efficiency of approximately 110.4%.

It can be seen that the display device including the second planarization layer made of the coating composition according to the embodiment exhibits light efficiency comparable to the light efficiency of the display device including the second planarization layer containing inorganic particles.

As described above, the display device according to the embodiment can prevent the issues of optical properties such as light scattering and light reflection caused by the inorganic particles included in the second planarization layer. The display device according to the embodiment can prevent a difference in the refractive index between the surface and the inner region of the second planarization layer and prevent mechanical characteristics from deteriorating.

Embodiments have been disclosed herein, and although terms are employed, they are used and are to be interpreted in a generic and descriptive sense only and not for the purpose of limitation. In some instances, as would be apparent to one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A coating composition comprising:
a first monomer represented by Chemical Formula 1 or Chemical Formula 2;
a second monomer comprising an acrylate monomer;
a photoinitiator;
a surfactant; and
a solvent: 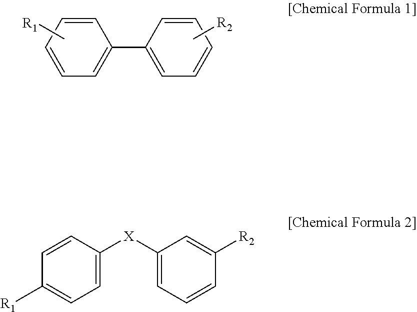
wherein in Chemical Formula 1 and Chemical Formula 2,
R₁ and R₂ are each independently hydrogen, 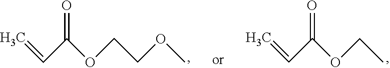
and
X is O or S.

2. The coating composition of claim 1, wherein the first monomer represented by Chemical Formula 1 or Chemical Formula 2 is represented by one of the following formulas: 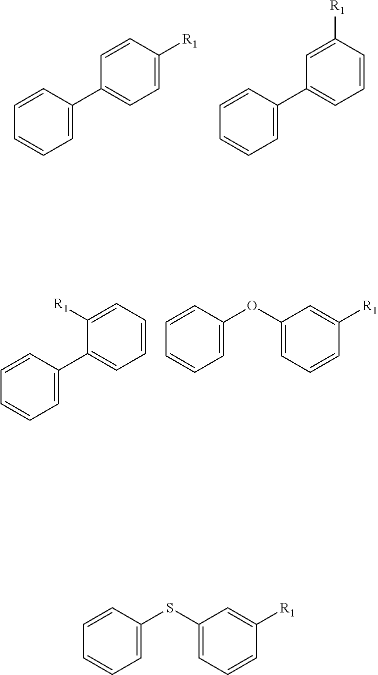
wherein in the formulas above,
R₁ is

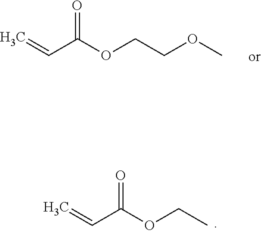

3. The coating composition of claim 2, wherein the first monomer represented by Chemical Formula 1 is the following compound:

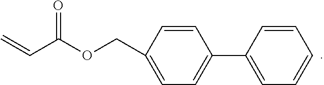 [SMILES: C=CC(=O)OCc1ccc(-c2ccccc2)cc1]

4. The coating composition of claim 1, wherein the first monomer represented by Chemical Formula 1 or Chemical Formula 2 is represented by one of the following formulas: 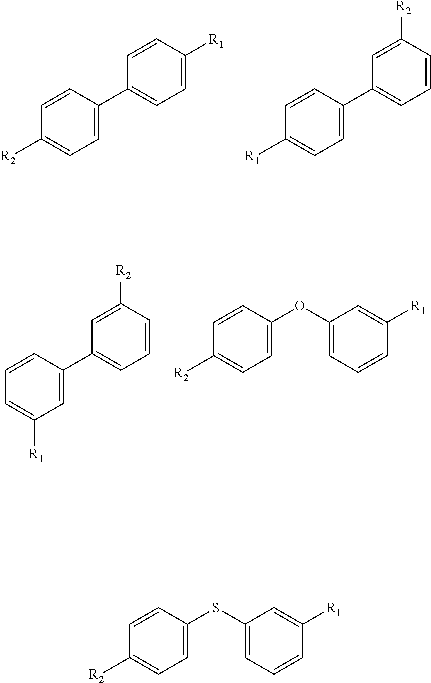
wherein in the formulas above,
R₁ and R₂ are each independently hydrogen,

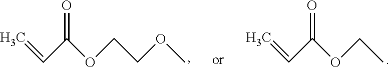

5. The coating composition of claim 1, wherein the second monomer comprises a polyethylene glycol diacrylate or a diol diacrylate.

6. The coating composition of claim 1, wherein a solid content of the composition per 100 wt %, excluding the solvent, includes:
about 50 wt % to about 90 wt % of the first monomer,
about 5 wt % to 40 about wt % of the second monomer,
about 0.1 wt % to about 10 wt % of the photoinitiator, and
about 0.1 wt % to about 10 wt % of the surfactant.

7. The coating composition of claim 1, wherein a content of the solvent is in a range of about 50 wt % to 90 wt %, per 100 wt % of the total coating composition.

8. The coating composition of claim 1, wherein a viscosity of the coating composition is in a range of about 10 cps to about 25 cps.

9. The coating composition of claim 1, wherein a surface tension of the coating composition is in a range of about 22 mN/m to about 30 mN/m.

10. A display device comprising:
a light-emitting element disposed on a substrate, the light-emitting element comprising:
a first electrode;
an organic emitting layer;
a second electrode; and
an emission area;
a first planarization layer disposed on the light-emitting element and comprising an opening portion overlapping the emission area; and
a second planarization layer disposed on the first planarization layer and covering the opening portion, wherein
the second planarization layer comprises:
a first monomer represented by Chemical Formula 1 or Chemical Formula 2;
a second monomer comprising an acrylate monomer;
a photoinitiator; and
a surfactant: 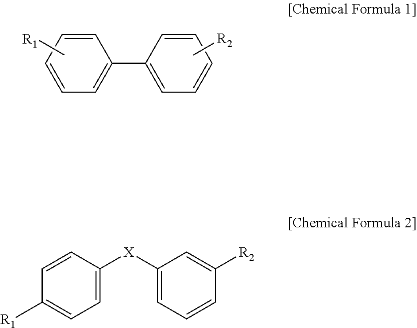
wherein in Chemical Formula 1 and Chemical Formula 2,
R₁ and R₂ are each independently hydrogen, 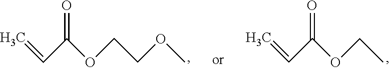
and
X is O or S.

11. The display device of claim 10, wherein the first monomer represented by Chemical Formula 1 or Chemical Formula 2 is represented by one of the following formulas: 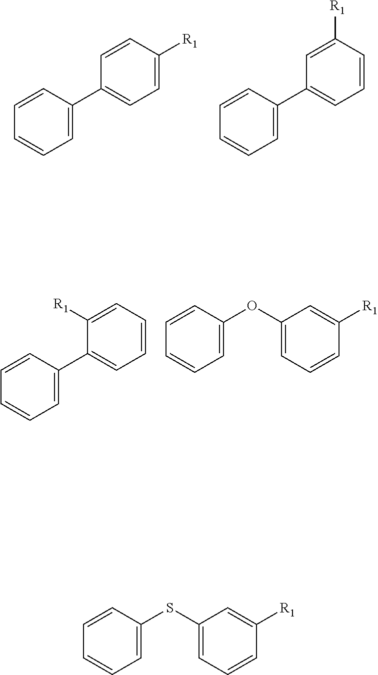
wherein in the formulas above,
R₁ is

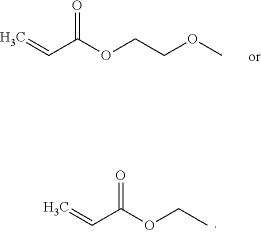

12. The display device of claim 11, wherein the first monomer represented by Chemical Formula 1 is the following compound:

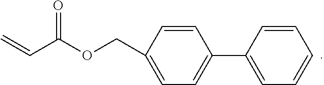 [SMILES: C=CC(=O)OCc1ccc(-c2ccccc2)cc1]

13. The display device of claim 10, wherein the first monomer represented by Chemical Formula 1 or Chemical Formula 2 is represented by one of the following formulas: 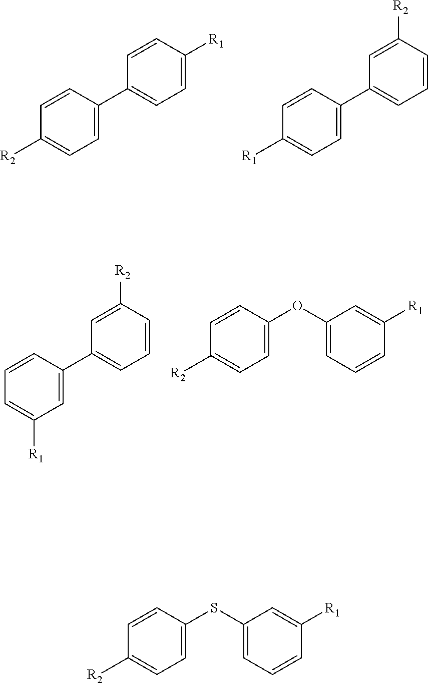
wherein in the formulas above,
R₁ and R₂ are each independently hydrogen,

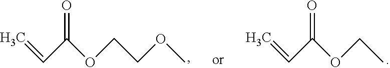

14. The display device of claim 10, wherein the second monomer comprises a polyethylene glycol diacrylate or a diol diacrylate.

15. The display device of claim 10, wherein a refractive index of the second planarization layer is in a range of about 1.58 to about 1.65.

16. The display device of claim 10, wherein the refractive index of the second planarization layer is greater than a refractive index of the first planarization layer by 0.05 or more.

17. The display device of claim 10, wherein a modulus of the second planarization layer is in a range of about 0.1 GPa to about 1.5 GPa.

18. The display device of claim 10, wherein an elongation of the second planarization layer is equal to or greater than about 5%.

19. The display device of claim 10, wherein side surfaces of the first planarization layer form an inner circumferential surface of the opening portion having a regular taper angle.

20. The display device of claim 10, further comprising:
a thin-film encapsulation layer disposed between the light-emitting element and the first planarization layer; and
a touch sensor layer disposed between the thin-film encapsulation layer and the first planarization layer.
